(19) United States
(12) Patent Application Publication
(10) Pub. No.: US 2017/0031142 A1
(43) Pub. Date: Feb. 2, 2017

(54) APPARATUS GENERATING EXTREME ULTRAVIOLET LIGHT AND EXPOSURE SYSTEM INCLUDING THE SAME

(71) Applicant: SAMSUNG ELECTRONICS CO., LTD., Suwon-si (KR)

(72) Inventors: Eokbong KIM, Hwaseong-si (KR); Mun Ja KIM, Suwon-si (KR); Jongju PARK, Hwaseong-si (KR); Donggun LEE, Hwaseong-si (KR); Byunggook KIM, Seoul (KR)

(21) Appl. No.: 15/183,015

(22) Filed: Jun. 15, 2016

(30) Foreign Application Priority Data
Jul. 29, 2015 (KR) 10-2015-0107298

(51) Int. Cl. G02B 19/00; G03F 7/20; H05G 2/00

(52) U.S. Cl. CPC G02B 19/0095; H05G 2/001; G03F 7/70033

(57) ABSTRACT

An extreme ultraviolet (EUV) light generation apparatus includes a source supplying unit in a chamber, the source supplying unit including a source material for generation of extreme ultraviolet light, a plasma generator to generate plasma from the source material, an optical unit in the chamber, and at least one protection film adjacent to the optical unit, the at least one protection film including at least one of graphite or graphene.

### CROSS-REFERENCE TO RELATED APPLICATION

Korean Patent Application No. 10-2015-0107298, filed on Jul. 29, 2015, in the Korean Intellectual Property Office, and entitled: “Apparatus Generating Extreme Ultraviolet Light and Exposure System Including the Same,” is incorporated by reference herein in its entirety.

### BACKGROUND

1. Field

Example embodiments relate to an apparatus generating extreme ultraviolet (EUV) light and an exposure system including the same, and in particular, to an apparatus generating extreme ultraviolet light and a system configured to perform an exposing process using extreme ultraviolet light.

2. Description of the Related Art

A photolithography process may include a photoresist coating step of forming a photoresist layer on a semiconductor substrate, a soft-bake step of curing the photoresist layer (e.g., by removing solvent from the photoresist layer), an exposure step of transcribing an image of photomask patterns onto the cured photoresist layer, a development step of developing the photoresist layer to form photoresist patterns, and a post-bake step of curing photoresist patterns. As the reduction in pattern size of a semiconductor device continues, it is necessary to reduce the wavelength of light used for the exposure step, and thus, extreme ultraviolet light is being currently used for the exposure step. For example, the extreme ultraviolet light is used for some exposure or test steps.

### SUMMARY

According to example embodiments, an extreme ultraviolet (EUV) light generation apparatus may include a source supplying unit in a chamber, the source supplying unit including a source material for generation of extreme ultraviolet light, a plasma generator to generate plasma from the source material, an optical unit in the chamber, and at least one protection film adjacent to the optical unit, the at least one protection film including at least one of graphite or graphene.

According to example embodiments, an exposure system may include a light source system configured to generate light, an optical system configured to control and pattern the light, and a substrate system configured to perform an exposure process on a substrate using the patterned light. The light source system may include a source supplying unit, a plasma generating unit configured to generate plasma from a source material supplied from the source supplying unit, a chamber providing a room for generation of the light, an optical unit provided in the chamber and configured to generate the light, a first protection film provided in the chamber to protect the optical unit from the light. The first protection film may include at least one of graphite or graphene.

According to example embodiments, an EUV generation apparatus may include a vacuum chamber, a source unit supplying a source material into the vacuum chamber, a light source configured to generated light including extreme ultraviolet light from the source material, an optical unit configured to allow the extreme ultraviolet light of the light to pass therethrough, and a protection film configured to protect the optical unit from the extreme ultraviolet. The protection film may include graphene.

According to example embodiments, a system for a chamber for generating extreme ultraviolet (EUV) light includes an optical unit in a light path of the generated extreme ultraviolet light, and at least one protection film in the light path of the extreme ultraviolet light before the optical unit, the at least one protection film including at least one of graphite or graphene.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic diagram of an EUV light generation apparatus according to example embodiments.

FIG. 2 illustrates a schematic diagram of an EUV light generation apparatus according to example embodiments.

FIG. 3 illustrates a schematic diagram of an EUV light generation apparatus according to example embodiments.

FIG. 4 illustrates a schematic diagram of an EUV light generation apparatus according to example embodiments.

FIG. 5 illustrates a schematic diagram of an EUV light generation apparatus according to example embodiments.

FIG. 6 illustrates a graph showing EUV light transmittance over a thickness of a protection film.

FIG. 7 illustrates a graph showing a difference in EUV light power between the presence and absence of the protection film.

FIG. 8 illustrates a graph showing a temporal variation in EUV light power, when the protection film is present.

FIG. 9 illustrates a schematic diagram of an EUV light generation apparatus according to example embodiments.

FIG. 10 illustrates a schematic diagram of an exposure system according to example embodiments.

FIG. 11 illustrates a schematic diagram of an exposure system according to example embodiments.

### DETAILED DESCRIPTION

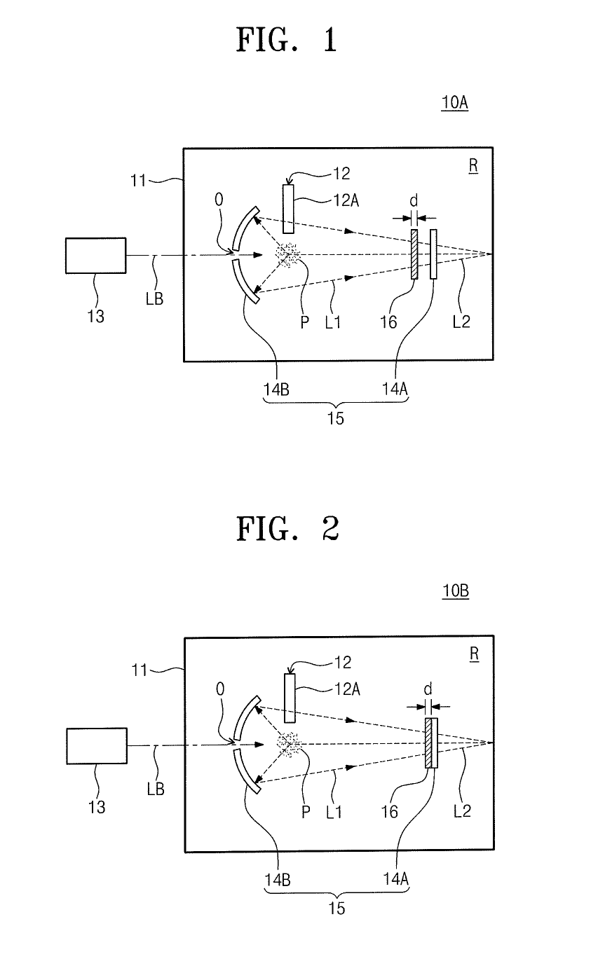

FIG. 1 is a schematic diagram illustrating an extreme ultraviolet (EUV) light generation apparatus 10A according to example embodiments. FIG. 2 is a schematic diagram illustrating an EUV light generation apparatus 10B according to example embodiments. The EUV light generation apparatuses 10A, 10B may be configured to generate EUV light having a wavelength ranging from about 10 nm to about 50 nm, e.g., a wavelength of about 13.5 nm.

Referring to FIG. 1, the EUV generation apparatus 10A may include a chamber 11, a source supplying unit 12, a plasma generator 13, an optical unit 15, and a protection film 16.

The chamber 11 may provide a room R, in which the EUV light is generated. The chamber 11 may be a vacuum chamber. Although not shown, the chamber 11 may include a vacuum pump, a vacuum gauge, and so forth. The use of the vacuum chamber may make it possible to prevent a fraction of the EUV light generated therein from being absorbed, e.g., by air molecules. In some embodiments, an EUV light L2 may be generated using high temperature plasma P, and thus, inner parts of the chamber 11 may be formed of at least one material that can be prevented from being damaged by the high temperature plasma P.

The source supplying unit 12 may supply a source for generating the EUV light. The source supplying unit 12 may be provided in the chamber 11. In some embodiments, the source supplying unit 12 may serve as a target 12A. For example, the target 12A may contain a solid source material. As an example, the source material may be provided on a surface of the target 12A. The source material may contain at least one of, e.g., xenon (Xe), lithium (Le), tin (Sn), neon (Ne), argon (Ar), or compounds thereof. In FIG. 1, the target 12A is shown to be provided at a position that does not correspond to an opening O of a condensing unit 14B, but in certain embodiments, the target 12A may be provided at a position corresponding to the opening O.

The plasma generator 13 may produce, e.g., generate, plasma P from the source material. The plasma generator 13 may be provided outside the chamber 11. Referring to FIG. 1, the plasma generator 13 may include a laser-produced plasma (LPP) source that is configured to emit a laser beam LB. For example, when the laser beam LB emitted from the plasma generator 13 is irradiated onto the source material of the source supplying unit 12, the interaction between the laser beam LB and the source material causes evaporation of the source material and generation of the plasma P. Further, the interaction between the generated plasma P and the source material triggers photon emission, i.e., light L1 generated from the plasma P. The light L1 may be multi-chromatic light with various wavelengths, e.g., a part of the light L1 may be used as the EUV light L2 to be described later. The laser beam LB may be a pulse with high intensity. For example, the plasma generator 13 may include a discharge-produced plasma (DPP) unit configured to produce plasma using a high voltage to the source material. In another example, the plasma generator 13 may be configured to produce CO₂ laser, NdYAG laser, free electron laser (FEL), ArF excimer laser, F₂ fluoride dimer laser, or KrF excimer laser.

The optical unit 15 may be disposed in the chamber 11. The optical unit 15 may be configured to extract the EUV light L2 from the light L1. The optical unit 15 may include a filter 14A and a condenser 14B, e.g., the filter 14A and condenser 14B may be spaced apart from each other to define a space therebetween for generating the plasma P. The condenser 14B may be configured to gather the light L1 produced from the plasma P. For example, the condenser 14B may be configured to reflect a fraction of the light L1 incident thereon toward the filter 14A, so the reflected light L1 is focused through the filter 14A to emit the EUV light L2, e.g., of a predetermined wavelength. In some embodiments, the condenser 14B may be provided to have an antenna shape with an opening O, e.g., the opening O may be positioned to allow the laser beam LB therethrough. This shape of the condenser 14B may allow the light L1 produced from the plasma P to be gathered, e.g., and reflected back toward the filter 14A, as described above. The filter 14A may be configured to allow the reflected light L1 (from the condenser 14B) to pass therethrough to emit the EUV light L2. The filter 14A may include a zirconium-containing component.

The protection film 16 may be disposed in the chamber 11. The protection film 16 may be configured to protect the optical unit 15 against the light generated by the plasma P, e.g., light L1 that includes wavelengths corresponding to EUV light. As an example, the protection film 16 may protect the optical unit 15 against thermal energy and debris which may be produced as a result of generating the plasma P, e.g., against generated light L1 that includes wavelengths corresponding to EUV light. In addition, the protection film 16 may be configured to minimize or reduce transmittance of light having a wavelength that is different from that of the EUV light L2. The protection film 16 may be formed of or include graphite (C). The protection film 16 may include a graphite-containing film or graphene. The protection film 16 may have a thickness d of about 0.1 nm to 300 nm.

For example, the protection film 16 may include graphene and a frame supporting the graphene. Except for the frame, there may be no need for any other supporter to be provided in the protection film 16. When viewed along a propagation path of light from the condenser 14B toward the filter 14A, the protection film 16 may be disposed in front of the optical unit 15. For example, as shown in FIG. 1, the protection film 16 may be disposed in front of the filter 14A, e.g., between the condenser 14B and the filter 14A. In other words, the protection film 16 may be provided to allow the reflected fraction of light L1 to be incident on the optical unit 15 therethrough, i.e., the reflected light L1 may be incident on the filter 14A through the protection film 16. Accordingly, the reflected light L1 may pass through the protection film 16, and then may be incident on the optical unit 15, i.e., incident on the filter 14A to be emitted as the EUV light L2.

For example, the protection film 16 may be disposed spaced apart from the optical unit 15. As an example, as shown in FIG. 1, the protection film 16 may be disposed spaced apart from the filter 14A.

In another example, the protection film 16 may be coupled to the optical unit 15. As an example, as shown in FIG. 2, the protection film 16 may be provided to be in, e.g., direct, contact with the filter 14A. The protection film 16 may be disposed on the optical unit 15, without an additional adhesive layer. In addition, the protection film 16 may be configured without any other supporter, except for the frame.

Although not shown, the chamber 11 may include a gas spraying unit, which is configured to spray gas toward the source material, thereby preventing adsorption of particles produced from the source material. The chamber 11 may further include, e.g., a pulse-width controller.

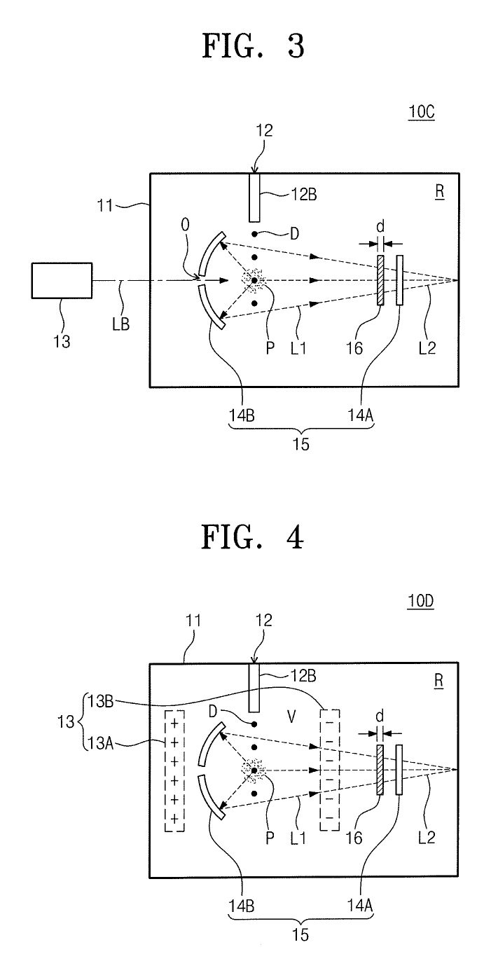

FIG. 3 is a schematic diagram illustrating an EUV light generation apparatus 10C according to example embodiments. Referring to FIG. 3, the EUV light generation apparatus 10C may include the chamber 11, the source supplying unit 12, the plasma generator 13, the optical unit 15, and the protection film 16. The chamber 11, the plasma generator 13, the optical unit 15, and the protection film 16 of FIG. 3 may be configured to have the same or similar shape or function as those of FIG. 1. For the sake of brevity, the elements and features of this example that are similar to those previously shown and described will not be described in much further detail.

According to the current embodiment, as illustrated in FIG. 3, the source supplying unit 12 may supply a source for generating the EUV light. The source supplying unit 12 may include a source part 12B configured to produce droplets D. In detail, the source part 12B may be provided in the chamber 11 to produce droplets D moving in a downward direction, so the laser beam LB emitted from the plasma generator 13 may interact with the droplet D (rather than with a surface of the target 12A) to generate the plasma P. The source supplying unit 12 may further include an imaging part of collecting a droplet image containing information on a position of the droplet D, and a control unit configured to perform a feedback process on the droplet D based on the droplet image.

FIG. 4 is a schematic diagram illustrating an EUV light generation apparatus 10D according to example embodiments. Referring to FIG. 4, the EUV light generation apparatus 10D may include the chamber 11, the source supplying unit 12, the plasma generator 13, the optical unit 15, and the protection film 16. The chamber 11, the source supplying unit 12, the optical unit 15, and the protection film 16 of FIG. 4 may be configured to have the same or similar shape or function as those of the EUV light generation apparatus 10B described with reference to FIG. 3. For the sake of brevity, the elements and features of this example that are similar to those previously shown and described will not be described in much further detail.

According to the current embodiment, as illustrated in FIG. 4, the plasma generator 13 may include a discharge-produced plasma (DPP) unit configured to produce plasma by applying high voltage to the source material. For example, the plasma generator 13 may be configured to apply a high voltage V to the droplet D. The plasma generator 13 may include a first electrode 13A and a second electrode 13B, which are disposed at opposite sides of the droplet D, and are spaced apart from each other, e.g., the condenser 14B may be between the first and second electrode 13A and 13B. Although the plasma generator 13 is schematically illustrated in FIG. 4, the shape and structure of the plasma generator 13 may be variously changed. As an example, the plasma generator 13 may include a circular grid and so forth. In certain embodiments, the EUV light generation apparatus 10D may further include a gas supplying part or an antenna part, allowing the plasma to be more efficiently generated.

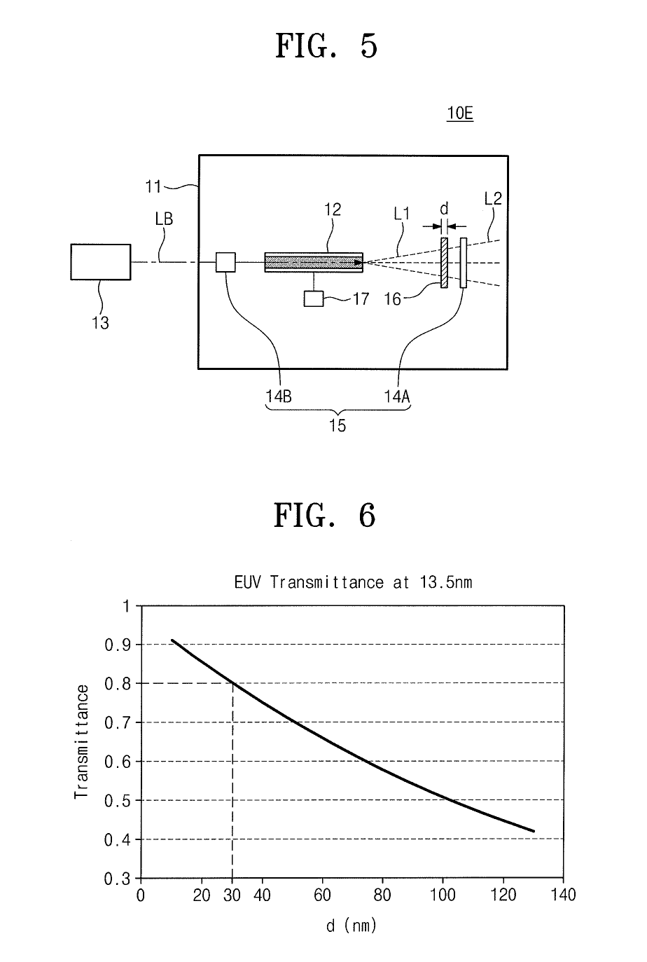

FIG. 5 is a schematic diagram illustrating an EUV light generation apparatus 10E according to example embodiments. Referring to FIG. 5, the EUV light generation apparatus 10E may include the chamber 11, the source supplying unit 12, the plasma generator 13, the optical unit 15, and the protection film 16. The chamber 11, the filter unit 14A, and the protection film 16 of the EUV light generation apparatus 10E of FIG. 5 may be configured to have the same or similar shape or function as those of the EUV light generation apparatus 10D described with reference to FIG. 4. For the sake of brevity, the elements and features of this example that are similar to those previously shown and described will not be described in much further detail.

The EUV generation apparatus 10E of FIG. 5 may include a high harmonic generator. The source supplying unit 12 may be configured to generate high-order harmonics. The source supplying unit 12 may be filled with an inert gas and may serve as a target. In some embodiments, the source supplying unit 12 may include an inert gas (e.g., helium (H2), neon (Ne), argon (Ar), or xenon (Xe). The plasma generator 13 may include a femtosecond laser. In the case where the laser LB emitted from the plasma generator 13 is incident into the source supplying unit 12, the laser LB may interact with the inert gas or a mixture gas thereof contained in the source supplying unit 12 to cause ionization and recombination of electrons. The light L1 may be produced by this process, e.g., emitted from the source supplying unit 12 toward the filter 14A, and may have an energy corresponding to a sum of the ionization energy and the kinetic energy of the electron may be produced. Alternatively, the EUV light generation apparatus 10E may further include the laser beam condenser 14B and a gas pressure controlling unit 17. In certain embodiments, the EUV light generation apparatus 10E may further include a pulse beam controller. Although the EUV light generation apparatus 10E is schematically illustrated in FIG. 5, the structure of the EUV light generation apparatus 10E may be variously changed to generate high-order harmonics.

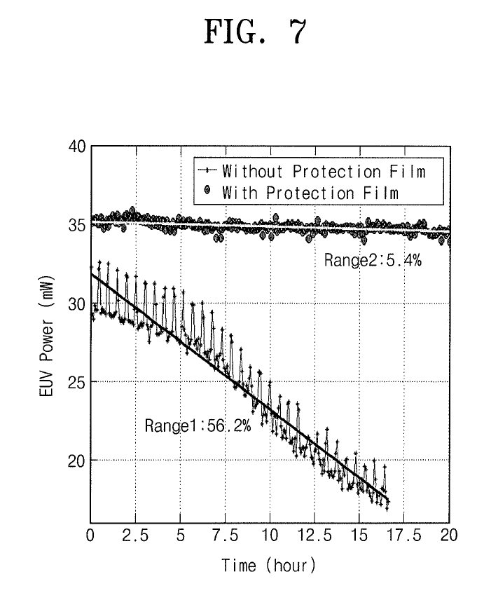

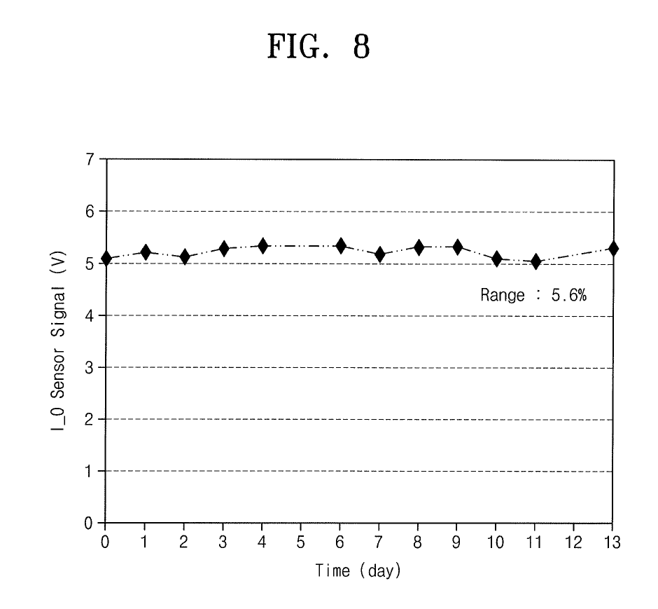

FIG. 6 is a graph showing transmittance of light over the thickness d of the protection film 16 of FIGS. 1 through 5. FIG. 7 is a graph comparing an output power of the EUV light L2 emitted from an apparatus according to an embodiment and an apparatus without the protection film 16. FIG. 8 is a graph showing a temporal variation in output power of the EUV light L2, when the protection film 16 is present. Hereinafter, the protection film 16 will be described with reference to FIGS. 6 through 8.

The protection film 16 contain graphite (C), e.g., the protection film 16 may contain graphene. Hereinafter, graphene will be compared with a material for the optical unit 15, e.g., with zirconium (Zr) of the filter 14A.

The zirconium has Mohs hardness of about 5, thermal conductivity of about 22.6 W/mK, and Young's modulus of about 88 Gpa. In contrast, the graphene has Mohs hardness higher than that of zirconium (Zr). For example, the hardness of the graphene may be higher than two times that of a diamond having Mohs hardness of about 10. Accordingly, the use of the graphene may make it possible to prevent damage caused by debris.

Also, the graphene has high thermal conductivity. For example, the thermal conductivity of the graphene may range from about 3000 W/mK to about 50000 W/mK. Accordingly, the use of the graphene may make it possible to reduce damage caused under high temperature process environment.

In addition, the graphene has a high Young's modulus. For example, the graphene may have Young's modulus of about 1300 GPa. Accordingly, the use of the graphene may make it possible to reduce damage caused by a change in process pressure.

In other words, the graphene may have physical properties superior to a material constituting the optical unit 15. Accordingly, when the protection film 16 formed of, e.g., consisting essentially of, graphene is positioned in front of a zirconium filter, e.g., between EUV light and the zirconium filter, damage to the zirconium filter may be prevented or substantially minimized.

In some embodiments, the graphene may be provided to have a thickness d ranging from about 0.1 nm to about 30 nm. Referring to FIG. 6, if the thickness d of the graphene is less than 30 nm, the EUV light transmittance through the protection film 16 is about 0.8 or higher. Accordingly, the use of the protection film 16 may make it possible to protect parts or neighboring components from the EUV light, and moreover, to prevent transmittance of the EUV light from being excessively changed in such a protection process.

Referring to FIG. 7, if the protection film 16 were to be removed from the EUV light generation apparatuses 10A and 10B, there would be a variation of about 56.2% in the output power of the EUV light L2, after the EUV generation apparatuses 10A and 10B are continuously operated for 16 hours. In contrast, in the case where the protection film 16 was provided in the EUV generation apparatuses 10A and 10B, there was a variation of only about 5.4% in the output power of the EUV light L2, after the EUV generation apparatuses 10A and 10B are continuously operated for 16 hours. Also, there was a difference in half-life of the output power of the EUV light L2. For example, as shown in FIG. 7, the half-life of the output power of the EUV light L2 was about 18.4 hours in the case with no protection film and about 582 hours in the case with the protection film 16.

Referred to FIG. 8, in the case where the protection film 16 was provided in the EUV light generation apparatuses 10A and 10B, there was no significant variation in the output power of the EUV light L2 for about two weeks. For example, as shown in FIG. 8, there was a variation of about 5.6% in sensor signals, which were produced from the measurement of the output power of the EUV light L2.

In other words, the use of the protection film 16 may make it possible to protect the optical unit 15 against EUV light, e.g., light L1 that includes the EUV light L2. Accordingly, it is possible to increase a replacement period of the optical unit 15. As a result, it is possible to reduce down-times of the EUV light generation apparatuses 10A and 10B and, consequently, to improve process efficiency.

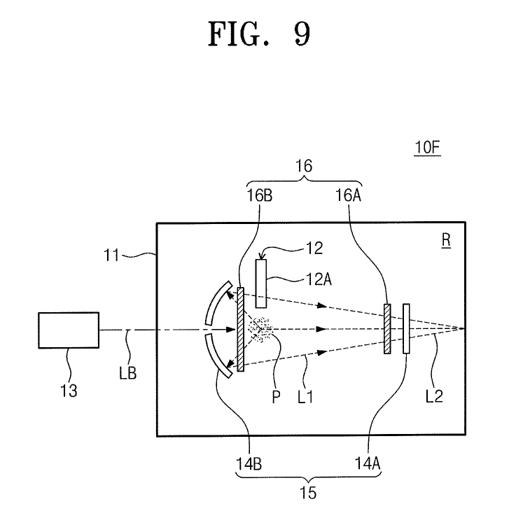

FIG. 9 is a schematic diagram illustrating an EUV light generation apparatus 10F according to example embodiments. Referring to FIG. 9, the EUV light generation apparatus 10F may include the chamber 11, the source supplying unit 12, the plasma generator 13, the optical unit 15, and the protection film 16. The chamber 11, the source supplying unit 12, the plasma generator 13, and the optical unit 15 of FIG. 9 may be configured to have the same or similar shape or function as those of the EUV light generation apparatus 10A described with reference to FIG. 1. For the sake of brevity, the elements and features of this example that are similar to those previously shown and described will not be described in much further detail.

According to example embodiments, as illustrated in FIG. 9, the number of the protection films 16 may be two or more. For example, the protection film 16 may include a first protection film 16A and a second protection film 16B. As shown in FIG. 9, the first protection film 16A may be disposed in front of the filter unit 14A, and the second protection film 16B may be disposed in front of the condensing unit 14B, e.g., so the plasma generation P may occur between the first and second protection films 16A and 16B.

Here, the expression “in front of” may be construed based on a propagation direction of the EUV light. For example, the expression “a first object is disposed in front of a second object” may be used to express that the first object is positioned adjacent to the second object to allow the light to be incident onto the second object through the first object. The first protection film 16A may be configured to protect the filter 14A from the EUV light. The second protection film 16B may be configured to protect the condenser 14B from the EUV light. In some embodiments, a plurality of first protection films 16A and a plurality of second protection films 16B may be provided in the chamber 11. When viewed along the propagation path of the light L1, the first protection film 16A may be disposed to be overlapped with the second protection film 16B, and this may make it possible to prevent or suppress the EUV light generation apparatus 10F from being affected by the EUV light.

While two protection films 16A and 16B for protecting the condenser 14B and the filter 14A are illustrated in FIG. 9, example embodiments are not limited thereto. For example, in the case where the number of optical parts provided in the chamber 11 is increased, the number of the protection films provided in the chamber 11 may be also increased by a same proportion. Furthermore, if the number of the protection films 16 is two or more, technical limitations on positions of the protection films 16 may be relaxed.

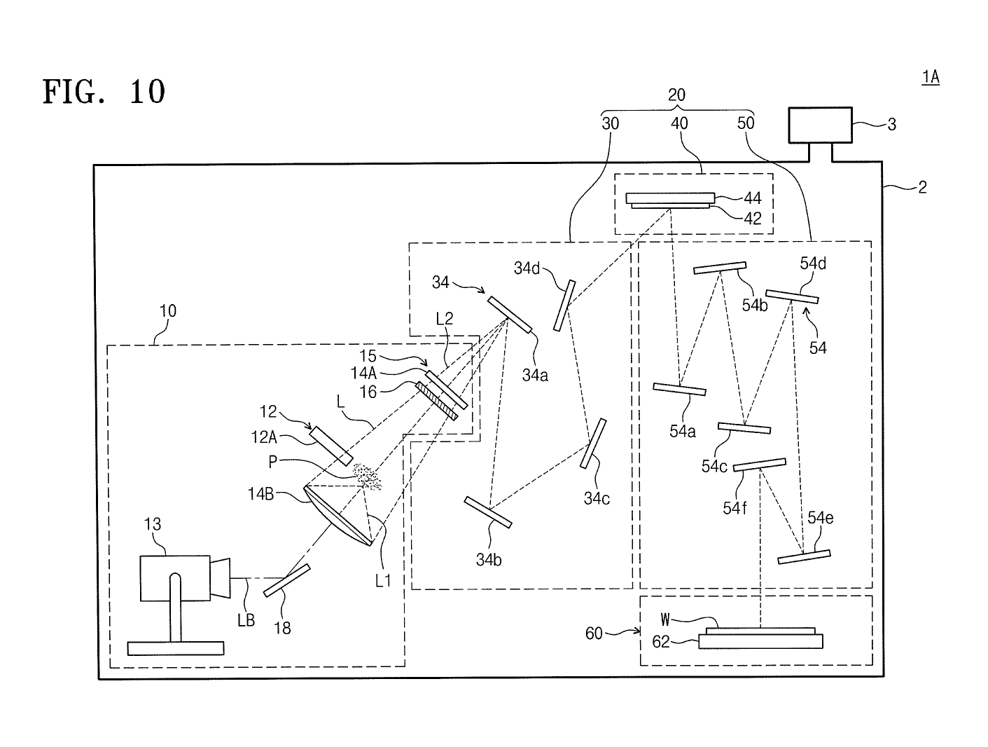

FIG. 10 is a schematic diagram illustrating an exposure system 1A according to example embodiments. The exposure system 1A may include one of the EUV light generation apparatuses 10A through 10F according to example embodiments. Referring to FIG. 10, the exposure system 1A may include a chamber 2, a light source system 10, an optical system 20, and a substrate system 60. The light source system 10, the optical system 20, and the substrate system 60 may be disposed in the chamber 2. The chamber 2 may be a vacuum chamber. The chamber 2 may include a vacuum pump 3.

The light source system 10 may be configured to generate light. The light generated by the light source system 10 may be used for an exposure process on the substrate W. In some embodiments, the light source system 10 may be configured to generate extreme ultraviolet (EUV) light. As an example, the light source system 10 may be configured to generate EUV light having a wavelength range from about 10 nm to about 50 nm. For example, the light source system 10 may be configured to generate EUV light having a wavelength of about 13.5 nm. It is noted that the chamber 11 is not illustrated in FIG. 10 to reduce complexity in the drawings. Furthermore, for the sake of brevity, the elements and features of this example that are similar to those previously shown and described will not be described in much further detail.

The optical system 20 may include an illuminating optical system 30, a mask system 40, and a projecting optical system 50. The optical system 20 may control and pattern the light. For example, the optical system 20 may control the propagation path of the light or intensity profile. The illuminating optical system 30 may be configured to transmit light from the light source system 10 to the mask system 40. The mask system 40 may be configured to pattern the light incident from the illuminating optical system 30. The projecting optical system 50 may be configured to transmit the patterned light from the mask system 40 to the substrate system 60.

The illuminating optical system 30 may include a first reflecting member 34. The first reflecting member 34 may include a mirror. As an example, the first reflecting member 34 may be a multi-layered mirror. The first reflecting member 34 may include a plurality of first sub reflecting members 34a, 34b, 34c, and 34d. FIG. 10 shows an example in which four sub first reflecting members (e.g., 34a, 34h, 34c, and 34d) are provided, but the number and positions of the first reflecting members are not limited to the example shown in FIG. 10. The first sub reflecting members 34a, 34b, 34c, and 34d may be disposed to transmit the EUV light L2, which is incident from the light source system 10, to the mask system 40. The first sub reflecting members 34a, 34b, 34c, and 34d may be disposed to meet technical requirements (e.g., in uniformity and spatial variation of intensity) for the EUV light L2. The illuminating optical system 30 may include a gas supplying member. The gas supplying member may be configured to supply a cleaning gas (e.g., argon (Ar), hydrogen (H₂), or nitrogen (N₂)). In certain embodiments, the illuminating optical system 30 may further include its own vacuum chamber or vacuum pump. Furthermore, the illuminating optical system 30 may further include various lenses and/or optical components.

The mask system 40 may include a reticle 42 provided with circuit patterns and a reticle stage 44 supporting the reticle 42. The mask system 40 may be configured to pattern light incident from the illuminating optical system 30. For example, the mask system 40 may be configured to selectively reflect light incident from the illuminating optical system 30. The mask system 40 may be configured to allow the patterned light to be incident into the projecting optical system 50.

The projecting optical system 50 may include a second reflecting member 54. The projecting optical system 50 may be configured to realize a reduction projection lithography process. The illuminating optical system 30 and the projecting optical system 50 may be connected to each other (e.g., in a single housing). In certain embodiments, the illuminating optical system 30 and the projecting optical system 50 may be provided in different housings, respectively. The second reflecting member 54 may include at least one mirror. As an example, the second reflecting member 54 may be a multi-layered mirror. The second reflecting member 54 may include a plurality of second sub reflecting members (e.g., 54a, 54b, 54c, 54d, 54e, and 54f). FIG. 10 shows an example in which six second sub reflecting members (e.g., 54a, 54b, 54c, 54d, 54e, and 540 are provided, but the number and positions of the second reflecting members are not limited to the example shown in FIG. 10. The second sub reflecting members 54a, 54b, 54c, 54d, 54e, and 54f may be configured to transfer the patterned light from the mask system 40 to the substrate system 60. The projecting optical system 50 may include a gas supplying member. The gas supplying member may be configured to supply a cleaning gas (e.g., argon (Ar), hydrogen (H₂), or nitrogen (N₂)). In certain embodiments, the projecting optical system 50 may further include its own vacuum chamber or vacuum pump. Furthermore, the projecting optical system 50 may further include various lenses and/or optical components.

The substrate system 60 may include a supporting member 62. The substrate W may be loaded on a top surface of the supporting member 62. The supporting member 62 may further include a clamp immobilizing the substrate W. In certain embodiments, the supporting member 62 may be configured to support and immobilize the substrate W using a vacuum suction or electrostatic force. The light transmitted from the optical system 20 may be used to expose the substrate W and thereby to form patterns on the substrate W. A suction line 64 may be provided in the supporting member 62. The suction line 64 may be configured to remove contaminants from the substrate W (for example, by vacuum suction).

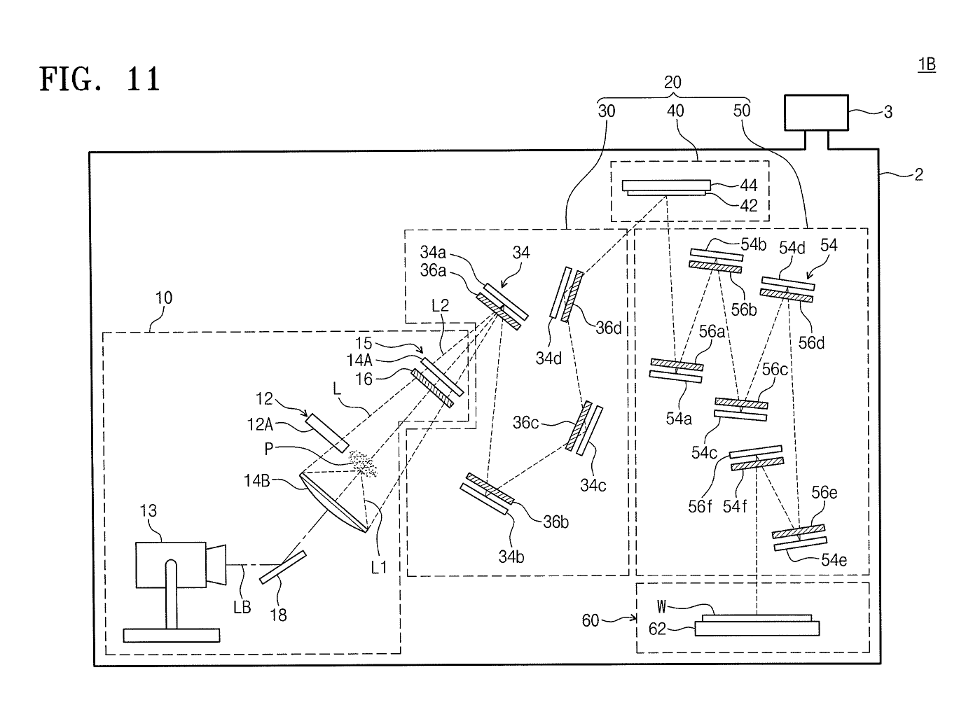

FIG. 11 is a schematic diagram illustrating an exposure system 1B according to example embodiments. Referring to FIG. 11, the exposure system 1B may include the chamber 2, the light source system 10, the optical system 20, and the substrate system 60. The chamber 2, the light source system 10, and the substrate system 60 of the exposure system 1B of FIG. 11 may be configured to have the same or similar shape or function as those of FIG. 10. For the sake of brevity, the elements and features of this example that are similar to those previously shown and described will not be described in much further detail.

The optical system 20 of FIG. 11 may further include a third protection film and a fourth protection film. The third and fourth protection films may be provided in the illuminating optical system 30 and the projecting optical system 50, respectively. The third and fourth protection films may be disposed in front of the propagation path of the EUV light L2, compared with the first and second reflecting members 34 and 54. This may make it possible to protect the first and second reflecting members 34 and 54. For example, as shown in FIG. 11, the third protection film may include third sub protection films 36a, 36b, 36c, and 36d, which are respectively provided in front of the first reflecting members 34a, 34b, 34c, and 34d, and the fourth protection film may include fourth sub protection films 56a, 56b, 56c, 56d, 56e, and 56f, which are respectively provided in front of the second reflecting members 54a, 54b, 54c, 54d, 54e, and 54f. However, the number and positions of the third and fourth protection films are not limited to the example shown in FIG. 10.

So far, an exposure system according to example embodiments has been exemplarily described with reference to the exposure systems 1A and 1B, in which one of the EUV light generation apparatuses 10A through 10F is provided. However, the EUV generation apparatuses 10A through 10F. As an example, the EUV generation apparatuses 10A through 10F may be used to realize a testing system using extreme ultraviolet light. For example, the EUV generation apparatuses 10A through 10F may be used to test a reticle using extreme ultraviolet light. In addition, although the illuminating optical system 30 and the projecting optical system 50 of the exposure system 10B has been described to include protection films, the mask system 40 may also be configured to include at least one protection film. According to example embodiments, the exposure systems 1A and 1B have been described to include the light source system 10, the optical system 20, and the substrate system 60 provided in the chamber 2, but each of the light source system 10, the optical system 20, and the substrate system 60 may be configured to have its own vacuum chamber. In addition, the protection film (e.g., containing graphene) may be disposed not only in front of the optical components but also in other regions, if such other regions are affected by the extreme ultraviolet light.

By way of summation and review, most materials have high absorption to EUV light. Thus, in the case of using EUV light, a reflective optical system, not a transmissive optical system (e.g., lens), should be adopted. However, the use of EUV light may lead to technical difficulties (e.g., high temperature heating or debris), which result in rapid deterioration of optical components and the consequent reduction in lifetime of the optical system.

Therefore, according to example embodiments, a graphene-containing protection film may be disposed in front of optical components of an EUV light generation apparatus, so it may be possible to prevent the optical components from being damaged in a process of generating or transferring extreme ultraviolet light. In addition, due to good characteristics (e.g., high hardness, good heat resistance, and good pressure resistance) of graphene, it is possible to increase a replacement period of the optical components and reduce a down-time of an EUV generation apparatus.

Accordingly, an EUV light generation apparatus (and an exposure system including the same) according to example embodiments may generate EUV light while preventing optical components from being damaged. Further, the EUV light generation apparatus allows the exposure system to be run with reduced downtime and improved process efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An extreme ultraviolet (EUV) light generation apparatus, comprising:
a source supplying unit in a chamber, the source supplying unit including a source material for generation of extreme ultraviolet light;
a plasma generator to generate plasma from the source material;
an optical unit in the chamber; and
at least one protection film adjacent to the optical unit, the at least one protection film including at least one of graphite or graphene.

2. The apparatus as claimed in claim 1, wherein the optical unit includes a condenser to condense light generated from the plasma, the at least one protection film being in front of the condenser.

3. The apparatus as claimed in claim 2, wherein the optical unit further includes a filter to allow the generated extreme ultraviolet light to pass therethrough, an additional protection film being in front of the filter.

4. The apparatus as claimed in claim 2, wherein the protection film is coupled to the optical unit.

5. The apparatus as claimed in claim 2, wherein the protection film is spaced apart from the optical unit.

6. The apparatus as claimed in claim 2, wherein the at least one protection film includes a plurality of protection films.

7. The apparatus as claimed in claim 1, wherein the plasma generator includes at least one of a laser produced plasma (LPP) unit, a discharge produced plasma (DPP) unit, or a high harmonic generator.

8. The system as claimed in claim 1, wherein the at least one protection film is between the source supplying unit and the optical unit.

9. The system as claimed in claim 1, wherein a region adjacent to the source supplying unit is defined as a plasma generation region, the optical unit including a surface facing the plasma generation region, and the at least one protection film overlapping the entire surface of the optical unit.

10. An exposure system, comprising:
a light source system to generate light;
an optical system to control and pattern the generated light; and
a substrate system to perform an exposure process on a substrate using the patterned light,
wherein the light source system includes:
a source supplying unit in a chamber, the source supplying unit including a source material,
a plasma generator to generate plasma from the source material;
an optical unit in the chamber, and
a first protection film in the chamber and adjacent to the optical unit, the first protection film including at least one of graphite or graphene.

11. The exposure system as claimed in claim 10, wherein the first protection film has a thickness ranging from 0.1 nm to 30 nm.

12. The exposure system as claimed in claim 11, wherein the optical unit includes:
a condenser to condense light generated from the plasma; and
a filter to filter the condensed light,
wherein the first protection film is in front of the optical unit.

13. The exposure system as claimed in claim 12, wherein the optical system further comprises:
a reflector to control and pattern the light; and
a second protection film to protect the reflector from the light, the second protection film including at least one of graphite or graphene.

14. The exposure system as claimed in claim 13, wherein each of the first and second protection films includes a plurality of protection films.

15. The exposure system as claimed in claim 14, wherein the first and second protection films are on a propagation path of the light.

16. The exposure system as claimed in claim 10, wherein the plasma generator includes at least one of a laser produced plasma (LPP) unit, a discharge produced plasma (DPP) unit, or a high harmonic generation unit.

17. The exposure system as claimed in claim 16, wherein the light is extreme ultraviolet light.

18. A system for a chamber for generating extreme ultraviolet (EUV) light, the system comprising:
an optical unit in a light path of the generated extreme ultraviolet light; and
at least one protection film in the light path of the extreme ultraviolet light before the optical unit, the at least one protection film including at least one of graphite or graphene.

19. The system as claimed in claim 18, wherein the optical unit includes a condenser and a filter spaced apart from each other, the extreme ultraviolet light and plasma being generated in a space between the condenser and the filter.

20. The system as claimed in claim 19, wherein the at least one protection film is adjacent to at least one of the filter and the condenser, the at least one protection film being between a source of a source material and one of the filter and condenser.
